(19) United States
(12) Patent Application Publication
(10) Pub. No.: US 2026/0005100 A1
(43) Pub. Date: Jan. 1, 2026

(54) SEMICONDUCTOR PACKAGE WITH HOTSPOT CONTROL

(71) Applicant: Taiwan Semiconductor Manufacturing Company, LTD., Hsinchu (TW)

(72) Inventors: Sheng-Han Tsai, Hsinchu (TW); Wensen Hung, Zhubei (TW); Wei-Kong Sheng, Chu-Nan (TW); Tsung-Yu Chen, Hsinchu (TW); Yen-Pu Chen, Hsinchu (TW)

(21) Appl. No.: 18/754,393

(22) Filed: Jun. 26, 2024

(51) Int. Cl. H01L 23/38; H01L 23/367; H01L 23/498; H01L 25/065

(52) U.S. Cl. CPC H01L 23/38; H01L 23/3672; H01L 23/49816; H01L 23/49838; H01L 25/0655

(57) ABSTRACT

A semiconductor package includes one or more semiconductor dies, and a lid disposed on the one or more semiconductor dies. One or more thermoelectric coolers are disposed on or in the lid. Each thermoelectric cooler is positioned at a predetermined hotspot of the one or more semiconductor dies. In one method of operating such a semiconductor package, functions are run on one or more semiconductor dies of the semiconductor package. During the running of these functions, one or more predetermined hotspots of the one or more semiconductor dies are cooled by operating a thermoelectric cooler positioned at each respective predetermined hotspot.

### BACKGROUND

The following relates to semiconductor packages such as chip-on-wafer (CoW) packages, chip-on-wafer-on-substrate (CoWoS) packages, integrated fanout (InFO) packages, and other heat-generating semiconductor packages, to cooling methods for semiconductor packages, and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 diagrammatically illustrate a sectional view (FIG. 1) and a simplified perspective view (FIG. 2) of a semiconductor package with a lid that includes a thermoelectric cooler.

FIG. 2 diagrammatically illustrates a sectional view of the semiconductor package of FIG. 1.

FIGS. 3, 4, and 5 diagrammatically illustrate top views of some nonlimiting illustrative examples of a lid of a semiconductor package with one or more thermoelectric coolers disposed on or in the lid.

FIGS. 6A and 6B diagrammatically illustrate a sectional view (FIG. 6A) and a top view (FIG. 6B) of a lid of a semiconductor package, in which the lid includes two thermoelectric coolers.

FIGS. 7A and 7B diagrammatically illustrate a sectional view (FIG. 7A) and a top view (FIG. 7B) of a lid of a semiconductor package, in which the lid includes two thermoelectric coolers and two sidewall-positioned thermoelectric coolers disposed on or in a sidewall of the lid.

FIG. 8 shows a flowchart of a method of operating a thermoelectric cooler disposed on or in a lid of a semiconductor package to cool a predetermined hotspot of a semiconductor package based on feedback comprising a temperature measurement at or near the predetermined hotspot.

FIG. 9 shows a flowchart of a method of operating a thermoelectric cooler disposed on or in a lid of a semiconductor package to cool a predetermined hotspot of a semiconductor package based on feedback comprising monitored operation of the semiconductor package.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Thermal power management is a significant consideration in the design of semiconductor packages. Thermal power management approaches disclosed herein advantageously provide locally controlled active thermal management using one or more thermoelectric coolers strategically placed at predetermined hotspots of the semiconductor package. Such predetermined hotspots are localized areas where it is predetermined that heat generation is highest, at least when the semiconductor package is performing certain functions. For example, a system-on-chip (SoC) die that includes an integral graphical processing unit (GPU) may have a predetermined hotspot at the location of the integral GPU portion of the SoC die, where substantial heat is generated during computationally complex video rendering performed by the GPU. Other areas of the SoC die may not be expected to generate as much heat. Hence, in this nonlimiting illustrative example, a thermoelectric cooler is disposed on or in the lid of the semiconductor package at the location of the GPU portion of the SoC die of the semiconductor package. This provides localized cooling of the GPU hotspot.

Furthermore, thermal power management approaches disclosed herein advantageously provide time-dependent active cooling using such thermoelectric coolers. In the preceding example, the GPU is a predetermined hotspot, but it may only actually produce a high heat load (i.e., become an actual hotspot) during video rendering operations, while at other times the GPU may not produce such an actual hotspot. Advantageously, the thermoelectric cooler corresponding to the GPU can be operated only during semiconductor package operations such as video rendering when an actual hotspot is present. Such control can be based on monitoring the operation of the semiconductor package (e.g., to operate the thermoelectric cooler corresponding to the GPU portion of the SoC during video rendering and not during other times when the GPU load is low). Additionally or alternatively, such control can be based on active temperature monitoring using a temperature diode, thermocouple, or other temperature sensor integrated into the semiconductor package at the predetermined hotspot. For example, the temperature sensor can be disposed on or in the lid of the semiconductor package, or may be integrated into the SoC die at a location near the GPU.

Thermal power management approaches disclosed herein, in some embodiments, may be tightly integrated with the semiconductor package. For example, the power driver for operating the thermoelectric cooler can be integrated into one (or more) of the semiconductor die(s) of the semiconductor package. While this approach increases the total heat generated by the semiconductor package (since the thermoelectric cooler driver itself generates some heat), it is recognized herein that this approach can advantageously control targeted cooling of predetermined hotspots, thereby improving the efficacy of the thermal power management of the semiconductor package.

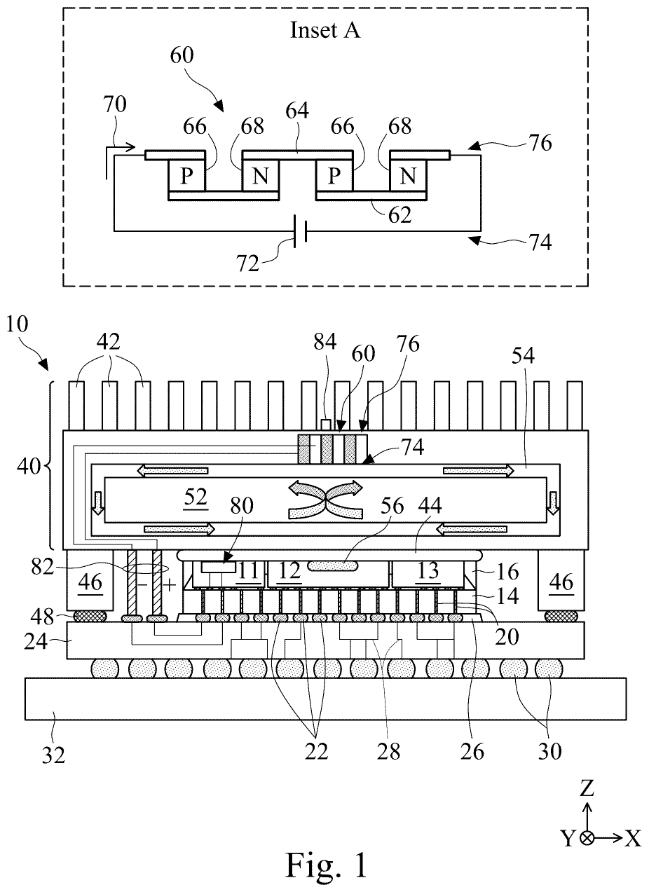

With reference now to FIG. 1, a semiconductor package 10 according to one nonlimiting illustrative embodiment is described. FIG. 1 diagrammatically illustrates a sectional view of the semiconductor package 10. As shown in FIG. 1, the semiconductor package 10 includes one or more (illustrative three) semiconductor dies 11, 12, 13 disposed on an interposer 14. More particularly, the one or more semiconductor dies 11, 12, 13 are disposed on a first (e.g., top or frontside) principal surface of the interposer 14. The one or more semiconductor dies 11, 12, 13 may in general include any type of semiconductor die or combination of types of semiconductor dies. By way of some nonlimiting examples, the one or more semiconductor dies 11, 12, 13 may include integrated circuit (IC) dies such as microprocessors, microcontrollers, system-on-chip (SoC) dies, central processing unit (CPU) dies, graphical processing unit (GPU) dies, solid-state memory dies, application-specific integrated circuits (ASICs), field-programmable gate arrays (FPGAs), photonic dies (e.g., semiconductor LEDs, lasers, photodetectors, various combinations thereof, and/or so forth. These are merely some nonlimiting illustrative examples. The one or more semiconductor dies 11, 12, 13 may be silicon or silicon-based dies, or group III-V semiconductor dies, silicon germanium and/or silicon carbide dies, various combinations thereof, or so forth. While each of the semiconductor dies 11, 12, 13 are illustrated as a single die, it is also contemplated for a given semiconductor die to itself be a stack of two (or more) semiconductor dies. An epoxy molding compound 16 or the like may surround the one or more semiconductor dies 11, 12, 13 and assist in structurally supporting the one or more semiconductor dies 11, 12, 13 on the interposer 14.

The interposer 14 may be a silicon interposer, although a sapphire interposer, a silicon carbide interposer, or other-material interposer is also contemplated. Electrical vias 20 pass through the interposer 14. In the case of a silicon interposer, the vias 20 may, for example, include through-silicon vias (TSV), e.g., made of copper in some nonlimiting illustrative embodiments, that pass through the (in this case silicon) interposer 14. It is also contemplated for the interposer 14 to include a redistribution layer (RDL, not shown) at one or both of the frontside and/or backside of the interposer 14. Inclusion of an optional RDL provides electrical pathways for redistributing electrical signals and/or power passing between the one or more semiconductor dies 11, 12, 13 and a second set of bonding bumps 24 disposed at the backside of the interposer 14.

At the backside of the interposer 14, bonding bumps 22 electrically and mechanically attach the assembly of the one or more semiconductor dies 11, 12, 13 and the interposer 14 to a first (e.g., top or frontside) principal surface of a substrate 24. An underfill material 26, such as an epoxy underfill in some nonlimiting illustrative embodiments, fills the space between the bonding bumps 22 and between the backside of the interposer 14 and frontside of the substrate 24 to structurally support the bonding bumps 22 and assist in bonding the backside of the interposer 14 to the frontside of the substrate 24.

The substrate 24 may be a silicon substrate (e.g., wafer or chip), although a sapphire substrate, a silicon carbide substrate, or other-material substrate is also contemplated. Electrical vias 28, metallization layers, or other electrical conductors pass through the substrate 24 to electrically connect the bonding bumps 22 at the frontside of the substrate 24 to backside or package-level bonding bumps 30 at a second (e.g., bottom or backside) principal surface of the substrate 24. In the case of a silicon substrate, the vias 28 may, for example, include through-silicon vias (TSV), e.g., made of copper in some nonlimiting illustrative embodiments, that pass through the (in this case silicon) substrate 24. It is also contemplated for the substrate 24 to include a frontside and/or backside RDL; such an optional RDL provides electrical pathways for redistributing electrical signals, for example to match a bonding pad array of a printed circuit board (PCB) or other mounting surface 32 on which the semiconductor package is mounted. The bonding bumps 22 may be solder bumps, tin bumps, tin-coated copper bonding balls, or so forth, and may be arranged as a ball grid array (BGA) matching a bonding pad array of the PCB or other mounting surface 32.

During operation, the one or more semiconductor dies 11, 12, 13 of the semiconductor package 10 may generate a substantial amount of heat. For example, on average an SoC or GPU die may operate at a few watts, and this power consumption can increase significantly during computationally intensive operations such as video rendering by a GPU or complex computations such as artificial intelligence (AI) training performed by a SoC, e.g., increasing to tens of watts, hundreds, or watts, or higher at peak power consumption. A significant portion of this operational power is converted to heat, leading to heating of the one or more semiconductor dies 11, 12, 13 and of the semiconductor package 10 as a whole.

To provide thermal management, the semiconductor package 10 further includes a lid 40 that promotes heat dispersion and removal. The illustrative lid 40 is made of a thermally conductive material such as by way of nonlimiting illustrative example copper, copper alloy, copper tungsten (CuW), aluminum or aluminum alloy, an aluminum-silicon-carbide (AlSiC) material, or the like, and includes heat fins 42 on a surface of the lid 40 that is distal from the one or more semiconductor dies 11, 12, 13. The lid is disposed over the one or more semiconductor dies 11, 12, 13, and a thermal interface material 44 is disposed between the one or more semiconductor dies 11, 12, 13 and the lid 40 to provide intimate thermally conductive contact between the one or more semiconductor dies 11, 12, 13 and the lid 40. The thermal interface material 44 may, by way of some nonlimiting illustrative examples, comprise indium, silver, copper, an indium alloy, a silver alloy, a copper alloy, or a solder material.

A ring 46 encircles the one or more semiconductor dies 11, 12, 13, and provides further structural support for the lid 40 on the substrate 24, and/or provides a seal for protecting the internal components of the semiconductor package 10 from ingress of environmental contaminants. A periphery of the lid 40 is secured to or supported by the ring 46. In some nonlimiting illustrative examples, the sealing and/or support ring 46 may comprise copper, a nickel-iron alloy such as alloy-42, a stainless steel such as SUS420, nickel, tungsten, copper-tungsten, copper-molybdenum, invar, or so forth. In the illustrative example, an adhesive 48 bonds the sealing and/or support ring 46 to the substrate 24. The ring 46 may also be secured to the lid 40 by an adhesive (not shown), or the ring 46 may be integral with the lid 40 (that is, the lid 40 and the ring 46 could be constructed as a single unitary component).

The lid 40 includes an integral vapor chamber 52 containing a working fluid. A wick layer 54 forms and/or is disposed on the interior surface(s) of the vapor chamber 52 to promote transfer of the working fluid by capillary action. The wick layer 54 provides a high surface area for promoting capillary action, and by way of nonlimiting illustrative example may comprise a weaving of small-diameter wires (e.g., copper or copper alloy wires), a sintered metal powder (e.g., copper powder), or so forth. In some nonlimiting illustrative embodiments, the wick layer 54 may have a thickness of between 0.1 mm and 0.5 mm, although a larger or small thickness outside this range is contemplated. The working fluid contained in the vapor chamber 52 vaporizes at temperatures produced at the wall of the vapor chamber 52 proximate to the one or more semiconductor dies 11, 12, 13, and condenses at lower temperatures present in portions of the vapor chamber 52 distal from that wall, thus producing thermal flow along the wicking layer 54 as diagrammatically indicated by arrows along the wick layer 54 in FIG. 1. The working fluid also may advantageously have a relatively high latent heat to promote the heat dispersion. In some nonlimiting illustrative examples, the working fluid contained in the vapor chamber 52 may comprise propylene glycol, water, methyl alcohol, or a mixture of two or more of these.

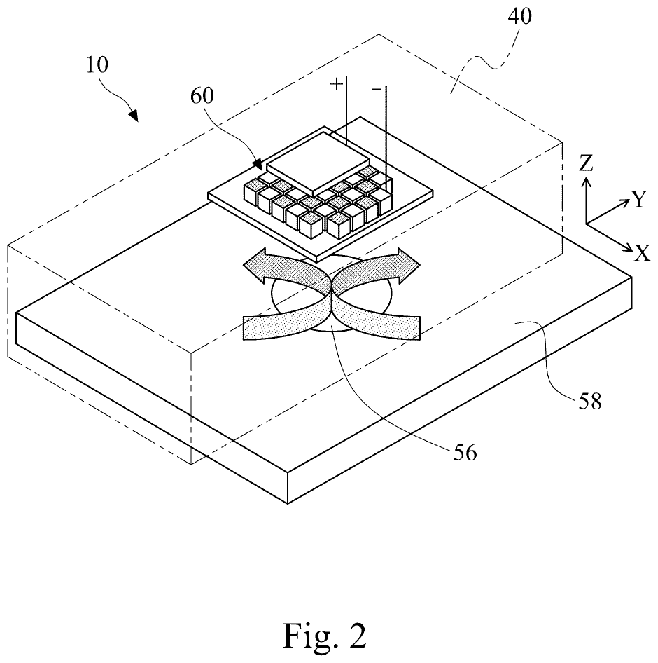

The vapor chamber 52 and its wick structure 54 operates as a heat spreader using the working fluid to carry heat from the hot surface proximate to the one or more semiconductor dies 11, 12, 13 to cooler distal surfaces in the vapor chamber 52. In some embodiments, the lateral area of the vapor chamber 52 is coextensive with or larger than the lateral area of the one or more semiconductor dies 11, 12, 13, as shown in FIG. 1. Without loss of generality, FIG. 1 and FIG. 2 each depict a Cartesian X-Y-Z direction system. In this Cartesian direction system, a lateral direction or lateral area is in (or parallel with) the X-Y plane, while a transverse direction is in (or parallel with) the Z-direction. Hence, the vapor chamber 52 in some embodiments has a lateral area that is greater than or equal to the lateral area of the one or more semiconductor dies 11, 12, 13, as is the case in illustrative FIG. 1.

The vapor chamber 52 and its wick layer 54 thus operates effectively as a lateral heat spreader for producing thermal flow and heat spreading in (or parallel with) the X-Y plane, as indicated by the arrows shown along the wick layer 54 indicating capillary flow of the working fluid. However, the vapor chamber 52 and its wick layer 54 is less effective at transferring heat in the Z-direction (i.e., the vertical direction in FIG. 1). Heat transfer in the Z-direction is supported by vaporized working fluid flowing from the surface proximate to the one or more semiconductor dies 11, 12, 13 to distal portions of the vapor chamber 52, as diagrammatically indicated in FIG. 1 by curved arrows. Additionally, the vapor condensation capacity can be limited (for example, if even the distal portions of the vapor chamber 52 are at a temperature above the vaporization temperature of the working fluid, then condensation of the working fluid may not occur). The vapor chamber 52 and its wick layer 54 can suffer local dry out at which point the heat transfer effectiveness is reduced.

With continuing reference to FIG. 1, a predetermined hotspot 56 in the semiconductor die 12 is diagrammatically indicated. The predetermined hotspot 56 is a localized area of the semiconductor die 12 where it is predetermined that the semiconductor package 10 generates a high amount of heat at least during some functions of the semiconductor package. In other examples (not shown), the predetermined hotspot could be an entire semiconductor die that produces more heat than the other semiconductor die(s) of the semiconductor package. The predetermined hotspot 56 may be an actual hotspot present whenever the semiconductor package 10 is operating, or the predetermined hotspot 56 may be an actual hotspot only when the semiconductor package 10 is running certain functions. By way of a nonlimiting illustrative example, the semiconductor die 12 may include a GPU portion corresponding to the predetermined hotspot 56, and the predetermined hotspot 56 may be an actual hotspot whenever the GPU portion is performing computationally intensive video rendering processing (and may not be an actual hotspot when the GPU portion is not operating, or is performing computationally simple rendering operations). As another example, the semiconductor die 12 may be a SoC die used to perform artificial intelligence (AI) model training, and the predetermined hotspot 56 may be a location of intensive computational processing performed by the SoC die. Here, the predetermined hotspot may be an actual hotspot whenever the such AI training is being performed (and may not be an actual hotspot when AI model training is not being performed). These are nonlimiting illustrative examples.

The predetermined hotspot 56 may be predetermined in various ways. In one approach, the integrated circuit (IC) layout of the one or more semiconductor dies 11, 12, 13 may be simulated using a circuit simulation program to determine which area or areas of the one or more semiconductor dies 11, 12, 13 will generated the most heat (and hence be predetermined hotspots). In another approach, the IC layout may be analyzed analytically to make this determination. For example, it may be known that a GPU portion of an IC is an actual hotspot during video rendering, and hence the location of the GPU portion may be a predetermined hotspot. In yet another approach, a prototype of the semiconductor package 10 may be fabricated and imaged using a thermal imaging camera during operation to empirically identify the predetermined hotspot 56. Combinations of these approaches may also be used to advantage.

With continuing reference to FIG. 1 and with further reference to FIG. 2, to address such problems and others the lid 40 further includes at least one thermoelectric cooler 60 disposed in or on the lid 40. FIG. 2 diagrammatically illustrates a simplified perspective view of the semiconductor package 10, in which the lid 40 is represented by a diagrammatic box 40 and the underlying components of the semiconductor package 10 are represented by a diagrammatic box 58.

As diagrammatically shown in FIG. 1, Inset A, the thermoelectric cooler 60 may be constructed as a Peltier cooling device, including electrical conductors 62 and 64 that electrically interconnect p-type regions 66 and n-type regions 68 in series. In response to an electrical current (diagrammatically indicated by arrow 70) flowing through the series-connected p-type regions 66 and n-type regions 68, e.g. driven by a voltage source 72 connected across the thermoelectric cooler 60, heat is transferred by the thermoelectric effect from a first side 74 to a second side 76. The p-type regions 66 and n-type regions 68 are suitably p-type semiconductor regions that are doped p-type and n-type semiconductor regions that are doped n-type, respectively. By way of some nonlimiting illustrative examples, the semiconductor material of the p-type and n-type regions 66 and 68 may be bismuth telluride, lead telluride, silicon-germanium, bismuth antimonide alloys, or so forth, although other semiconductor materials are contemplated. In some embodiments, electrically insulating but thermally conductive plates (not shown) provide thermal contact. The electrically insulating but thermally conductive plates may, for example, comprise ceramic plates such as ceramic beryllia (BeO) plates.

Referring again to the main drawing of FIG. 1, The thermoelectric cooler 60 is disposed in or on the lid 40. In the illustrative example of FIG. 1, the thermoelectric cooler 60 is disposed in the lid 40 between the integral vapor chamber 52 and the heat fins 42, and is positioned at the predetermined hotspot 56 of the one or more semiconductor dies 11, 12, 13. In this position, the thermoelectric cooler 60 (when operating, that is, when electrically powered by the voltage source 72) advantageously actively transfers heat away from the hotspot 56 in the vertical (i.e., Z-direction) and toward the heat fins 42 which then radiate the heat out into the ambient air (or other ambient fluid). It is noted that the lid 40 may be thin in the vertical or Z-direction, compared with the lateral area of the lid 40 in the lateral X-Y plane. Hence, the thermoelectric cooler 60 is positioned at the predetermined hotspot 56 by being placed at about the same X-Y position as the corresponding predetermined hotspot 56 (as best seen in the diagrammatic perspective view of FIG. 2), where it is located at (the lateral position of) the predetermined hotspot 56 and spaced apart from the predetermined hotspot 56 by a distance about equal to, or less than, the (relatively thin) thickness of the lid 40. In the illustrative position of the thermoelectric cooler 60 between the integral vapor chamber 52 and the heat fins 42, the thermoelectric cooler 60 assists in cooling of the distal surface of the vapor chamber 52, advantageously increasing the vapor condensation capacity of the vapor chamber 52 and reducing the likelihood of local dry out. It is estimated that the cooling capacity of the lid 40 may thereby be boosted by about 10% when the predetermined hotspot 56 is active.

Although not shown, the thermoelectric cooler could alternatively be placed at the X-Y position of the corresponding predetermined hotspot 56, but located vertically (i.e., in the Z-direction) between the predetermined hotspot 56 and the vapor chamber 52, where it would contribute to heat transfer from the predetermined hotspot 56 to the proximal surface of the vapor chamber 52.

It is further noted that in some embodiments, the lid may not include the integral vapor chamber, instead relying on the thermal conductivity of the copper, copper alloy, aluminum, or other material of the lid along with the active heat transfer provided by the thermoelectric cooler 60. This alternative approach can advantageously enable a reduction in the total thickness of the lid and hence place the thermoelectric cooler at (the lateral position of) the predetermined hotspot and closer to the hotspot (due to the thinner lid).

In another contemplated variant, rather than omitting the integral vapor chamber it may instead be replaced by another integral passive thermal management mechanism, such as a set of microchannels in the lid providing convective heat transfer, or embedded carbon nanowires to increase thermal conductivity of the lid in a direction along the nanowires, or so forth.

It is to be appreciated that the semiconductor package 10 of FIGS. 1 and 2 is a nonlimiting illustrative example. More generally, a semiconductor package includes one or more semiconductor dies, a lid disposed on the one or more semiconductor dies, and one or more thermoelectric coolers which are disposed on or in the lid, with each thermoelectric cooler being positioned at a predetermined hotspot of the one or more semiconductor dies. The semiconductor package may, by way of some further nonlimiting examples, be a chip-on-wafer (CoW) package, a chip-on-wafer-on-substrate (CoWoS) package (as illustrated), an integrated fanout (InFO) package, or substantially any other heat-generating semiconductor package with a lid. Moreover, while the illustrative thermoelectric coolers are disposed on or in the lid 40, it is contemplated for the thermoelectric coolers to be located elsewhere in the semiconductor package, such as being disposed on or in the substrate 24.

As previously noted, the thermoelectric cooler 60 is disposed in or on the lid 40. For example, the thermoelectric cooler 60 could be attached to an external surface of the lid 40, between two neighboring heat fins 42. In another example, the thermoelectric cooler 60 could be disposed in a recess formed in an external surface of the lid 40, for example between two neighboring heat fins 42. In another example, the thermoelectric cooler 60 could be embedded within the lid 40. These are merely some nonlimiting illustrative examples.

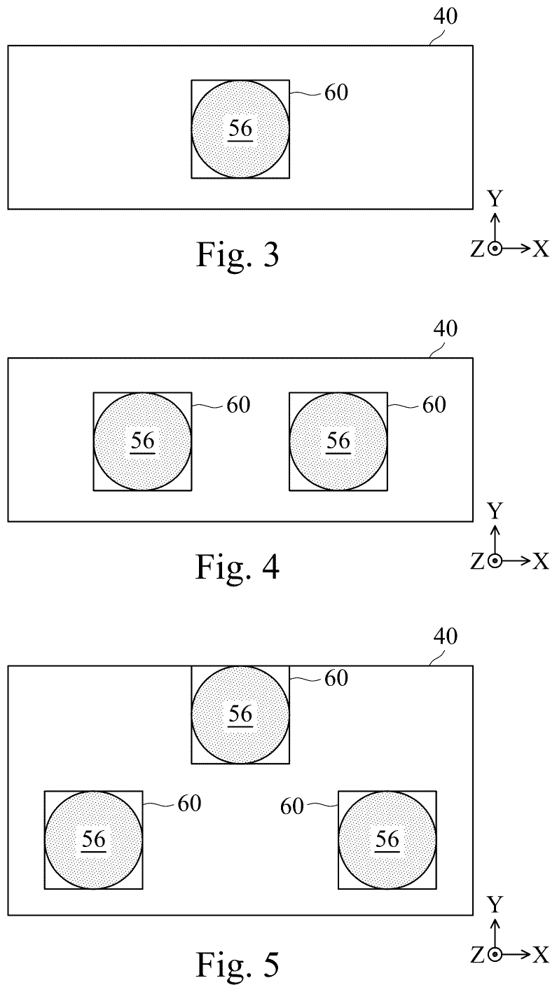

In the illustrative example of FIGS. 1 and 2, there is a single predetermined hotspot 56, and a single thermoelectric cooler 60 disposed on or in the lid 40 positioned at the predetermined hotspot 56. In other embodiments, there may be two or more thermoelectric coolers. FIGS. 3, 4, and 5 diagrammatically illustrate top views of three respective nonlimiting illustrative examples. The top views of FIGS. 3-5 show the lateral X-Y plane as indicated by the annotated X-Y-Z direction system which corresponds to the X-Y-Z direction system annotated in FIGS. 1 and 2. In FIGS. 3, 4, and 5, the predetermined hotspots 56 corresponding to the thermoelectric coolers are also diagrammatically indicated.

FIG. 3 presents an example corresponding to FIGS. 1 and 2, in which there is the single predetermined hotspot 56, and the single thermoelectric cooler 60 disposed on or in the lid 40 positioned at the single predetermined hotspot 56. FIG. 4 presents an example in which there are two predetermined hotspots 56, and two thermoelectric coolers 60, with each thermoelectric cooler 60 disposed on or in the lid 40 positioned at a corresponding predetermined hotspot 56. FIG. 5 presents an example in which there are three predetermined hotspots 56, and three thermoelectric coolers 60, with each thermoelectric cooler 60 disposed on or in the lid 40 positioned at a corresponding predetermined hotspot 56. These are merely nonlimiting illustrative examples, and four, five, six, or more hotspots and corresponding thermoelectric coolers are analogously contemplated, depending on the number of predetermined hotspots.

In the examples of FIGS. 3, 4, and 5, each predetermined hotspot 56 is circular, and the corresponding thermoelectric cooler 60 is square or rectangular. However, it is contemplated to employ a non-square and non-rectangular thermoelectric cooler, for example to more closely match the shape of the corresponding hot spot.

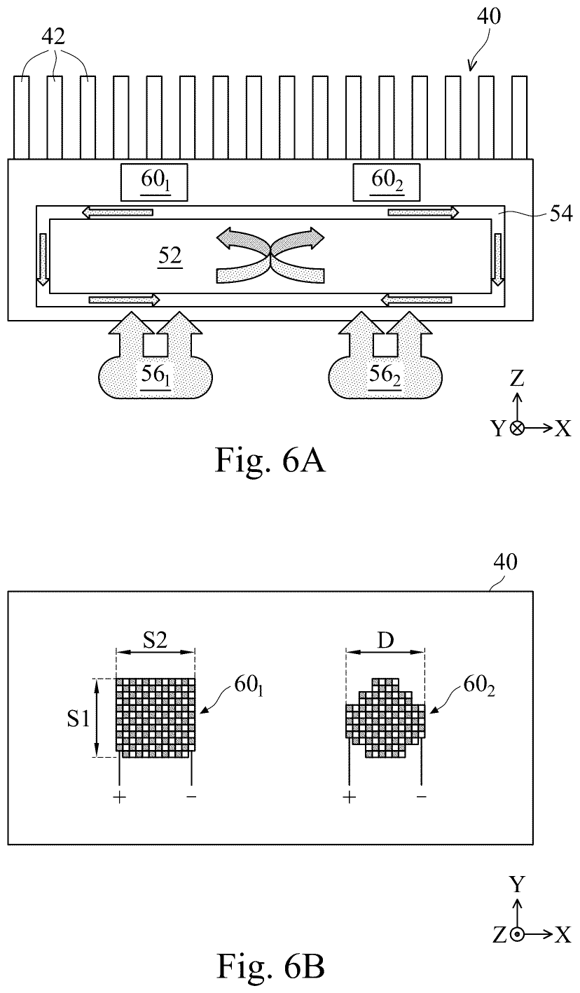

With reference to FIGS. 6A and 6B, such an example is presented. FIG. 6A shows a cross-sectional view of an embodiment of the lid 40, including the heat fins 42 and the integral vapor chamber 52 and its wick structure 54 as previously described with reference to FIG. 1. In this example, the one or more semiconductor dies (not shown in FIG. 6A) have two predetermined hotspots 56₁ and 56₂. A first thermoelectric cooler 60₁ is disposed on or in the lid 40 positioned at (the lateral position of) the first predetermined hotspot 56₁ of the one or more semiconductor dies, and a second thermoelectric cooler 60₂ is disposed on or in the lid 40 positioned at (the lateral position of) the second predetermined hotspot 56₂.

With particular reference to FIG. 6B, which shows a top view of the lid 40 with the X-Y-Z direction system again annotated, it is seen that in this nonlimiting illustrative example the first thermoelectric cooler 60₁ has a square or rectangular shape with annotated side lengths S1 and S2 (where S1=S2 if the first thermoelectric cooler 60₁ has a square shape; or S1≠S2 if the first thermoelectric cooler 60₁ has a non-square rectangular shape). By contrast, in this nonlimiting illustrative example the second thermoelectric cooler 60₂ has a circular shape with annotated diameter D. If the corresponding predetermined hotspot 56₂ (see FIG. 6A) has a circular shape, then the circular shape of the second thermoelectric cooler 60₂ may advantageously have diameter D matching the diameter of the circular second predetermined hotspot 56₂ to efficiently cool the area of the hotspot. Other shapes are contemplated for the thermoelectric cooler, such as oval, hexagonal, octagonal, or so forth, in some embodiments with the shape and its dimensions (e.g., S1, S2, D, . . . ) chosen to match the shape and dimensions of the corresponding predetermined hotspot.

In some nonlimiting illustrative embodiments, each thermoelectric cooler is sized to have a dimension (e.g., S1, S2, D, . . . ) that is between 1.5 and 2 times the corresponding dimension of the corresponding predetermined hotspot. This advantageously ensures the entire hotspot is actively cooled by the corresponding thermoelectric cooler, while still advantageously providing localized cooling. In some nonlimiting illustrative embodiments, each thermoelectric cooler has a dimension (e.g., S1, S2, D, . . . ) that is between 10 mm and 40 mm. In some embodiments, a lateral area of each thermoelectric cooler is less than or equal to 40% of the total lateral area of the one or more semiconductor dies 11, 12, 13, thus advantageously providing localized active cooling specifically targeting the one or more predetermined hotspots.

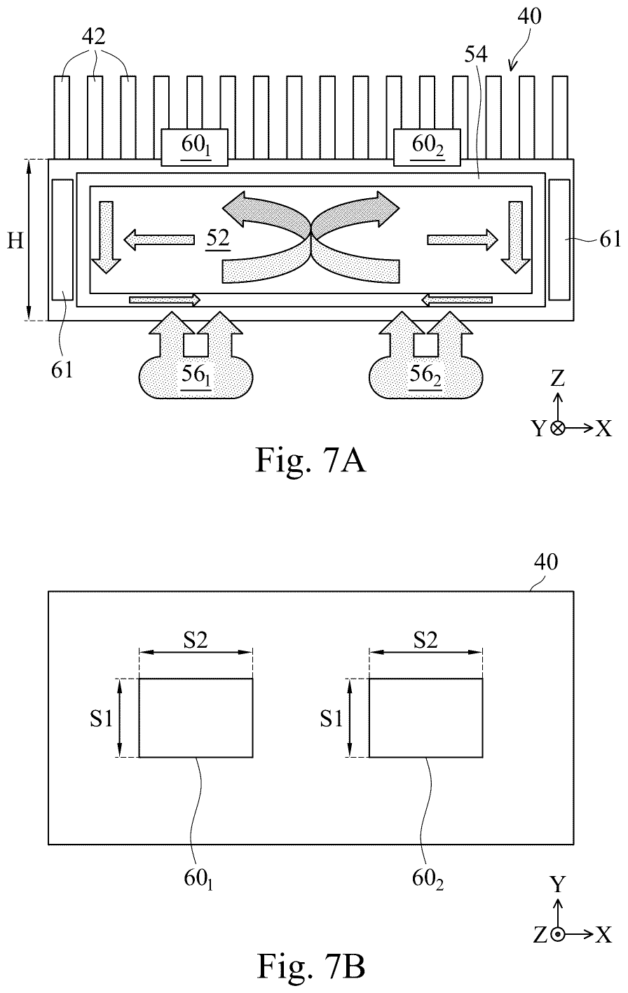

FIGS. 7A and 7B diagrammatically illustrate another embodiment by way of a sectional view (FIG. 7A) and a top view (FIG. 7B) of the lid 40. In this embodiment, the lid 40 again includes the heat fins 42 and the integral vapor chamber 52 and its wick structure 54 as previously described with reference to FIG. 1. There are two predetermined hotspots 56₁ and 56₂ and corresponding first and second thermoelectric coolers 60₁ and 60₂ disposed on or in the lid 40 positioned at (the lateral position of) the respective first and second predetermined hotspots 56₁ and 56₂. In this embodiment, as seen in FIG. 7B both thermoelectric coolers 60₁ and 60₂ have square or rectangular shapes with dimensions S1 and S2.

As seen in FIG. 7A, the lid 40 here differs from the previously described illustrative embodiments in that it further includes one or more (illustrative two) sidewall-positioned thermoelectric coolers 61 disposed on or in a sidewall of the lid 40. The sidewall-positioned thermoelectric coolers 61 advantageously enhance vapor condensation of the working fluid in the integral vapor chamber 52 on the surrounding periphery walls of the vapor chamber 52. In some embodiments, this advantageously enables increasing a thickness or height H of the lid 40 in the transverse or Z-direction, as indicated in FIG. 7A. (Note, the thickness or height H omits the height of the heat fins 42, as seen in FIG. 7A). The increased thickness or height H, in turn, increases the volume of the vapor chamber 52 and increases the total surface area of the wick layer 54, thereby increasing the vapor condensation capacity and cooling capacity of the vapor chamber 52.

In some nonlimiting illustrative embodiments, the height H of the lid 40 in the embodiment of FIGS. 7A and 7B is in a range of about 5 mm to about 15 millimeters.

In some nonlimiting illustrative embodiments, the thickness or height H of the lid 40 in the embodiment of FIGS. 7A and 7B is at least twice the thickness or height (in the Z-direction) of the one or more semiconductor dies.

In some nonlimiting illustrative embodiments, the height H of the lid 40 in the embodiment of FIGS. 7A and 7B is between two times and ten times the thickness of the package excluding the lid 40 (that is, the thickness of the sub-package including the one or more semiconductor dies 11, 12, 13, interposer 14, and substrate 24).

In some nonlimiting illustrative embodiments, an area ratio of the area of the sidewall-positioned thermoelectric coolers 61 to the periphery wall area of the sidewall of the lid 40 is 40% or less.

With returning reference to FIG. 1, the thermoelectric cooler 60 is operated by a voltage source 72 connected across the thermoelectric cooler 60, and when so operated the thermoelectric cooler 60 transfers heat by the thermoelectric effect from the first side 74 to a second side 76, thereby transferring heat from the vapor chamber 52 to the heat fins 42. In the illustrative example of FIG. 1, the one or more semiconductor dies (and specifically semiconductor die 11 in the illustrative example) includes an integrated driver circuit 80 connected to operate the one or more thermoelectric coolers 60 disposed on or in the lid 40. The integrated driver circuit 80 thus serves as the voltage source 72. The driving voltage is delivered from the integrated driver circuit 80 to the thermoelectric cooler 60 by way of illustrative conductors 82 and associated conductors formed in the substrate 24 and embedded in or disposed on the lid 40. The embodiment of FIG. 1A includes a single thermoelectric cooler 60 driven by the integrated driver circuit 80, but in embodiments such as those of FIGS. 4, 5, 6A, and 7A which have two or more thermoelectric coolers there may be a corresponding integrated driver circuit 80 for each respective thermoelectric cooler. The integrated driver circuit 80 may, for example, be a MOSFET-based constant voltage source integrated circuit or the like. In some embodiments, the integrated driver circuit 80 may advantageously be monolithically fabricated in the semiconductor die along with the SoC circuitry, GPU circuitry, or other functional circuitry of the semiconductor die.

While in the illustrative example of FIG. 1 the integrated driver circuit 80 is integrated in the one or more semiconductor dies 11, 12, 13, it is alternatively contemplated for the voltage source 72 to be otherwise provided, for example directly from the PCB or other mounting surface 32 on which the semiconductor package 10 is mounted.

In some embodiments, the one or more thermoelectric coolers 60 may operate continuously, or whenever the semiconductor package 10 is operative. This advantageously provides efficient, targeted, and active cooling of the predetermined hotspots 56 and thus advantageously improves the cooling capacity of the lid 40.

In some embodiments, the cooling capacity of the lid 40 is further increased by operating the one or more thermoelectric coolers 60 only at times when the predetermined hotspots 56 are active. In one approach, one or more (illustrative one) temperature sensors 84 may monitor the temperature of the lid 40 at the predetermined hotspot 56, and this monitored temperature is used to control the integrated driver circuit 80 to turn the thermoelectric cooler 60 on when the monitored temperature exceeds an upper threshold (TH), and to turn the thermoelectric cooler 60 off on when the monitored temperature falls below a lower threshold. While the illustrative temperature sensor 84 is in the lid 40, it may alternatively be monolithically integrated in the one or more semiconductor dies 11, 12, 13, for example as an integrated circuit optionally monolithically fabricated in the semiconductor die along with the SoC circuitry, GPU circuitry, or other functional circuitry of the semiconductor die. In embodiments with two or more predetermined hotspots and corresponding two or more thermoelectric coolers, each predetermined hotspot may be monitored by a separate temperature sensor. The temperature sensor 84 may, for example, be a temperature diode, a thermocouple, or so forth.

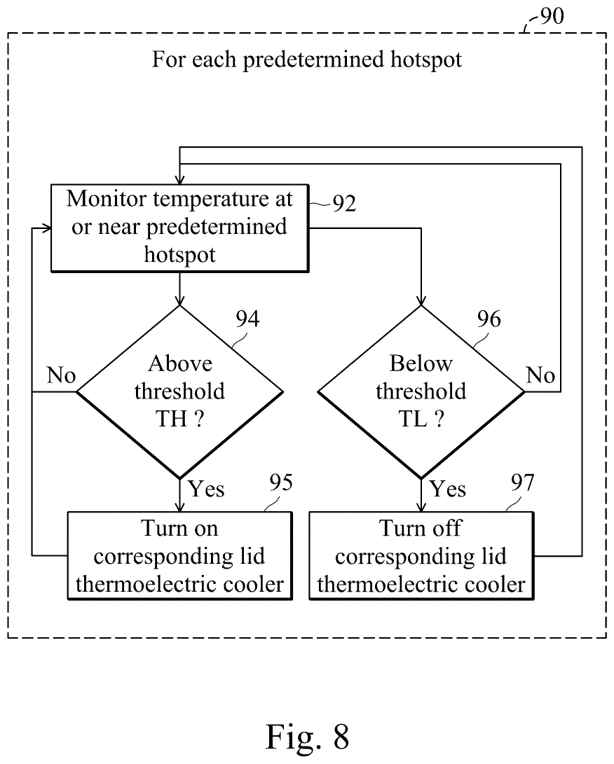

With reference to FIG. 8, a method 90 performed for each predetermined hotspot 56 is diagrammatically shown for controlling the corresponding thermoelectric cooler 60 based on the temperature monitored by the temperature sensor 84. In an operation 92 the temperature at or near the predetermined hotspot 56 is monitored, e.g., using the temperature sensor 84. In a decision block 94 it is determined whether the monitored temperature is above an upper threshold TH. If so, then in an operation 95 the integrated driver circuit 80 turns on (i.e. operates) the thermoelectric cooler 60 located at the predetermined hotspot 56 to begin active, targeted cooling of the hotspot 56. Conversely, in a decision block 96 it is determined whether the monitored temperature is below a lower threshold TL. If so, then in an operation 97 the integrated driver circuit 80 turns off (i.e. does not operate) the thermoelectric cooler 60 located at the predetermined hotspot 56 so that no active, targeted cooling of the hotspot 56 is performed.

In some embodiments, the upper threshold TH and the lower threshold TL may be the same. In other embodiments, the upper threshold TH is larger than the lower threshold TL. This provides a hysteresis effect, i.e., once the operation 95 turns on the thermoelectric cooler 60 at temperature TH cooling continues until the temperature falls below the lower temperature TL. This can advantageously provide smoother operation by preventing the thermoelectric cooler 60 from being rapidly switched on and off, which can occur when the monitored temperature is close to the threshold temperature TH=TL if these thresholds are the same.

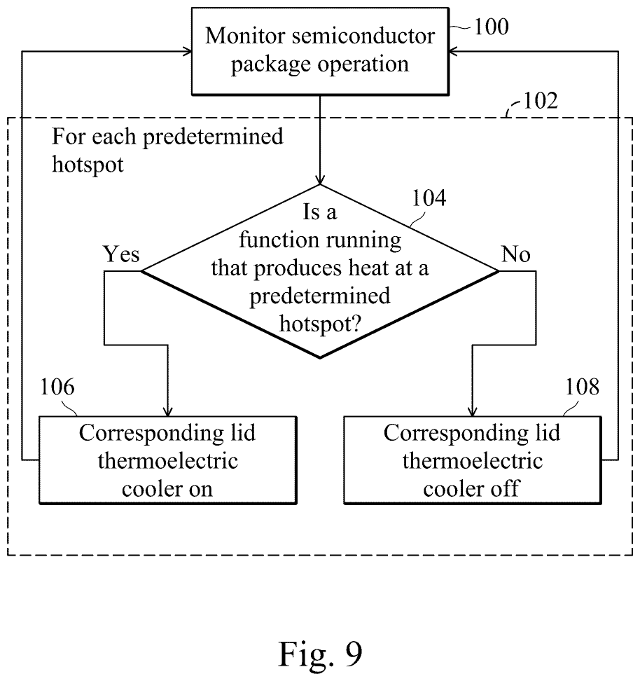

With reference to FIG. 9, another control method is described, in which the thermoelectric cooler 60 is turned on or off based on a function being run by the semiconductor package. In an operation 100, the operation of the semiconductor package 10 is monitored. A method 102 is performed for each predetermined hotspot 56 to operate the thermoelectric cooler 60 located at the predetermined hotspot based on this package functional information. In an operation 104, it is determined whether the semiconductor package 10 is running a function that produces heat at the predetermined hotspot. If such a function is running, then in an operation 106 the thermoelectric cooler 60 located at that predetermined hotspot 56 is turned on (i.e., is operated). If such a function is not running, then in an operation 108 the thermoelectric cooler 60 located at that predetermined hotspot 56 is turned off (i.e., is not operated).

By way of an illustrative example, consider a predetermined hotspot 56 corresponding to a GPU portion of an SoC die. In the operation 104 it is determined whether the SoC is running a video rendering function. If so, then the operation 106 is invoked to operate the thermoelectric cooler 60 located at the predetermined hotspot 56 corresponding to the GPU portion. If video rendering is not being performed, then the operation 108 is invoked to not operate the thermoelectric cooler 60 located at the predetermined hotspot 56 corresponding to the GPU portion. This approach is premised on recognition that the predetermined hotspot 56 corresponding to the GPU portion is expected to be active (i.e., producing substantial heat) only during video rendering.

An advantage of the control approach of FIG. 9 is that it does not require the temperature sensor 84. If the integrated driver circuit 80 is employed, which is integrated in the one or more semiconductor dies 11, 12, 13, then the operations 100 and 104 can be programmed into the functional integrated circuitry of the one or more semiconductor dies 11, 12, 13. In the above example, whenever video rendering is initiated the integrated driver circuit 80 is also turned on to operate the thermoelectric cooler 60 at the predetermined hotspot 56 corresponding to the GPU portion; and whenever video rendering is stopped the integrated driver circuit 80 is also turned off to stop operating the thermoelectric cooler 60 at the predetermined hotspot 56 corresponding to the GPU portion.

In the following, some further embodiments are described.

In a nonlimiting illustrative embodiment, a semiconductor package includes one or more semiconductor dies, and a lid disposed on the one or more semiconductor dies. One or more thermoelectric coolers are disposed on or in the lid. Each thermoelectric cooler is positioned at a predetermined hotspot of the one or more semiconductor dies.

In a nonlimiting illustrative embodiment, a method of operating a semiconductor package includes running functions on one or more semiconductor dies of the semiconductor package. During the running, one or more predetermined hotspots of the one or more semiconductor dies are cooled by operating a thermoelectric cooler positioned at each respective predetermined hotspot.

In a nonlimiting illustrative embodiment, a semiconductor package includes a substrate, one or more semiconductor dies disposed on the substrate, a ring disposed on the substrate and encircling the one or more semiconductor dies, a lid disposed on the one or more semiconductor dies and on the ring, and one or more thermoelectric coolers disposed on or in the lid. An area of each thermoelectric cooler is less than or equal to 40% of the total lateral area of the one or more semiconductor dies.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package comprising:
one or more semiconductor dies;
a lid disposed on the one or more semiconductor dies; and
one or more thermoelectric coolers disposed on or in the lid, each thermoelectric cooler being positioned at a predetermined hotspot of the one or more semiconductor dies.

2. The semiconductor package of claim 1, wherein the one or more thermoelectric coolers consist of two or more thermoelectric coolers.

3. The semiconductor package of claim 1, wherein the lid includes an integral vapor chamber having a wick layer formed on or disposed on an interior surface of the vapor chamber.

4. The semiconductor package of claim 3, further comprising:
a substrate on which the one or more semiconductor dies are disposed;
a thermal interface material disposed between the one or more semiconductor dies and the lid; and
a ring encircling the one or more semiconductor dies, the ring being secured to or integral with the lid.

5. The semiconductor package of claim 1, wherein the lid includes:
an integral vapor chamber having a wick layer formed on or disposed on an interior surface of the vapor chamber; and
heat fins disposed on a surface of the lid distal from the one or more semiconductor dies;
wherein the one or more thermoelectric coolers are disposed between the integral vapor chamber and the heat fins.

6. The semiconductor package of claim 1, further comprising:
one or more sidewall-positioned thermoelectric coolers disposed on or in a sidewall of the lid.

7. The semiconductor package of claim 6, wherein a height of the lid is at least twice a height of the one or more semiconductor dies.

8. The semiconductor package of claim 1, wherein:
a lateral area of the lid is equal to or greater than a total lateral area of the one or more semiconductor dies; and
a lateral area of each thermoelectric cooler is less than or equal to 40% of the total lateral area of the one or more semiconductor dies.

9. The semiconductor package of claim 1, wherein each thermoelectric cooler has a square, rectangular, circular, oval, hexagonal, or octagonal shape.

10. The semiconductor package of claim 1, wherein the one or more semiconductor dies includes an integrated driver circuit connected to operate the one or more thermoelectric coolers disposed on or in the lid.

11. The semiconductor package of claim 1, wherein:
each predetermined hotspot is a location where the one or more semiconductor dies are predetermined to produce heat when the semiconductor package is running a function that produces heat at the predetermined hotspot; and
the one or more semiconductor dies are configured to operate the thermoelectric cooler positioned at each predetermined hotspot only when the semiconductor package is running the function that produces heat at the predetermined hotspot.

12. The semiconductor package of claim 1, further comprising:
one or more temperature sensors;
wherein the one or more semiconductor dies are configured to operate the thermoelectric cooler positioned at each predetermined hotspot based on feedback from the one or more temperature sensors.

13. The semiconductor package of claim 1, wherein each thermoelectric cooler comprises a plurality of electrically interconnected p-type semiconductor regions and n-type semiconductor regions.

14. A method of operating a semiconductor package, the method comprising:
running functions on one or more semiconductor dies of the semiconductor package; and
during the running, cooling one or more predetermined hotspots of the one or more semiconductor dies by operating a thermoelectric cooler positioned at each respective predetermined hotspot.

15. The method of claim 14, wherein the cooling includes:
operating the thermoelectric cooler positioned at each respective predetermined hotspot only when the semiconductor package is running a function that produces heat at the predetermined hotspot.

16. The method of claim 14, wherein the cooling includes:
measuring a temperature of each predetermined hotspot during the running; and
operating the thermoelectric cooler positioned at each respective predetermined hotspot based on the measured temperature of the predetermined hotspot during the running.

17. The method of claim 14, wherein:
the one or more semiconductor dies includes an integrated driver circuit; and
the cooling includes operating each thermoelectric cooler using the integrated driver circuit of the one or more semiconductor dies.

18. A semiconductor package comprising:
a substrate;
one or more semiconductor dies;
a ring disposed on the substrate and encircling the one or more semiconductor dies;
a lid disposed on the one or more semiconductor dies and on the ring; and
one or more thermoelectric coolers disposed on or in the lid;
wherein an area of each thermoelectric cooler is less than or equal to 40% of the total lateral area of the one or more semiconductor dies.

19. The semiconductor package of claim 18, wherein the lid includes:
heat fins;
an integral vapor chamber having a wick layer formed on or disposed on an interior surface of the vapor chamber; and
a thermal interface material disposed between the one or more semiconductor dies and the lid.

20. The semiconductor package of claim 18, wherein:
the one or more semiconductor dies includes an integrated driver circuit connected to operate the one or more thermoelectric coolers disposed on or in the lid based on an input comprising a temperature measured by a temperature sensor and/or a function being run by the semiconductor package.
